(19) United States
(12) Patent Application Publication
(10) Pub. No.: US 2006/0094224 A1
(43) Pub. Date: May 4, 2006

(54) Bumping process and structure thereof

(75) Inventors: Min-Lung Huang, Kaohsiung (TW); Yi-Hsin Chen, Kaohsiung (TW); Jia-Bin Chen, Tainan (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/251,901

(22) Filed: Oct. 18, 2005

(30) Foreign Application Priority Data
Nov. 3, 2004 (TW) 93133439

(51) Int. Cl. H01L 21/44

(52) U.S. Cl. 438/612

(57) ABSTRACT

A bumping process is provided. The bumping process comprises the steps of: firstly, providing a wafer; next forming an under bump metallurgy (UBM) on the active surface of the wafer; then, forming a photo-resist layer on the active surface of the wafer and forming at least an opening in the photo-resist layer; then, sequentially forming a copper post, a barrier and a copper layer; then removing the photo-resist layer; finally reflowing the solder layer in the opening. The barrier layer is made of the materials such as nickel, lest the copper post and the solder layer might contact directly, causing the copper to diffuse fast and lose accordingly. Therefore, the quality of bumping process and structure can be enhanced according to the present invention.

This application claims the benefit of Taiwan application Serial No. 93133439, filed Nov. 3, 2004, the subject matter of which is incorporated herein by reference.

### BACKGROUND OF THE INVENTION

1. Field of the Invention

The invention relates in general to a semiconductor manufacturing process, and more particularly to a bumping process of wafer.

2. Description of the Related Art

In the semiconductor industry, the manufacturing process of integrated circuits (IC) is divided into three main stages: the manufacturing of wafer, the manufacturing of IC, and the package of IC. The die is manufactured according to the steps of manufacturing the wafer, performing circuit design, performing several mask manufacturing processes, and dividing the wafer. Every die formed by dividing the wafer is electrically connected to a carrier via a bonding pad disposed on the die to form a chip package structure. The chip package structure is further categorized into three types, namely, the wire bonding type, the flip chip bonding type, and the tape automatic bonding type.

Referring to FIG. 1˜FIG. 5, flowcharts of a bumping process of a conventional wafer are shown. At first, referring to FIG. 1, an under bump metallurgy 110 is formed on the entire surface of a wafer 100 and is covered up by a photo-resist layer 120. Next, referring to FIG. 2, several openings 122 are formed on a photo-resist layer 120 using the imaging technology of exposure and development, and the positions of the openings 122 correspond to several bonding pads 102 positioned on the wafer 100. Afterwards, referring to FIG. 3, [symbol] photo-resist layer 120 [symbol] the mask, [symbol] copper electroplating treatment, so that the educts of copper in the electroplating solution can be adhered onto a portion of the surface using the under bump metallurgy 110 as an electroplating-seed layer to form a bump structure similar to a copper pillar 112. Next, referring to FIG. 4, the same photo-resist layer 120 is used as the mask in the solder electroplating treatment to form a mushroom-like solder layer 114 on the surface of the copper pillar 112, while the solder layer 114 which can be made of materials such as tin-lead alloy with a low melting point for instance, can therefore be reflown to be a spherical bump via which every chip (not illustrated in the diagram) of the wafer 100 is electrically connected to an external circuit board (not illustrated in the diagram).

At last, Referring to FIG. 5, remove the photo-resist layer 120, and etch the under bump metallurgy 110 (retain the under bump metallurgy 110a under the copper pillar 112), and then to reflow the solder layer 114, to make the solder layer 114 be melted as a spherical solder bump 114a.

It is noteworthy that, due to the upper surface of the copper pillar 112 contact the solder bump 114a, so that copper is accelerated to lose because of the diffusion, thus the quality of the bump is reduced.

### SUMMARY OF THE INVENTION

It is therefore the object of the invention to provide a bumping process applicable to a wafer to enhance the quality of the copper pillar and the solder layer in the bumping process.

It is therefore the object of the invention to provide a bump structure applicable to a chip to enhance the quality of the copper pillar and the solder bump of the bump structure.

The invention provides a bumping process. The bumping process comprises the steps of: firstly, providing a wafer, wherein the wafer has several chips each having at least a bonding pad positioned on an active surface of the wafer; next, forming an under bump metallurgy (UBM) on the active surface of the wafer; then forming a photo-resist layer on an active surface of the wafer and forming at least an opening on the photo-resist layer; next, sequentially forming a copper post, a barrier, and a copper layer in the opening; next, removing the photo-resist layer; finally reflowing the solder layer in the opening.

According to the preferred embodiment of the invention, the formation of the above photo-resist layer comprises coating a photosensitive material and forming the opening using exposure and development. Besides, after the copper post and the barrier layer are sequentially formed, the embodiment further comprises forming a copper layer on the barrier layer disposed in the opening. Next, the solder layer is formed on the copper layer disposed in the opening by screen printing.

According to the preferred embodiment of the invention, before the formation of the above photo-resist layer, the embodiment further comprises forming a re-distribution layer (RDL) and/or an under bump metallurgy on an active surface of the wafer, wherein a portion of the surface of the under bump metallurgy is exposed in the opening. The method of forming an RDL comprises sputtering, evaporating or electroplating. Besides, in the step of forming the copper post, the under bump metallurgy can be used as an electroplating-seed layer to be dipped into an electroplating solution for the educts of copper to be adhered onto the under bump metallurgy disposed in the opening.

The invention provides a bump structure applicable to a chip having at least a bonding pad positioned on an active surface of the chip. The bump structure mainly comprises a column and a solder the bump. The column has a copper post, a barrier layer and a copper layer. The copper post connects the bonding pad, and the barrier layer is connecting the copper post and the copper layer. Besides, the solder bump is disposed on the copper layer of the column.

The invention provides a bump structure applicable to a chip having at least a bonding pad and positioned on an active surface of the chip. The bump structure mainly comprises a column and a solder the bump. The column has a copper layer and a resist layer, and copper layer is connected to the bonding pad and the barrier layer of the chip. Besides, the solder bump is disposed on the barrier layer of the column.

According to the preferred embodiment of the invention, the above thickness of the copper post can be larger than the thickness of the resist layer, and the thickness of the copper post can range from 10 nm to 100 nm, from 10 nm to 50 nm, or from 40 nm to 50 nm. Besides, the thickness of the barrier layer can be larger than 3 nm or smaller than 10 nm for instance. Besides, the thickness of the copper layer can be smaller than 1 nm for instance.

According to the invention, a barrier layer is formed between the copper post and the copper layer, or a barrier layer is formed between a copper layer and a solder layer, so that the loss of copper ions can be mitigated. Therefore, the solder bump can be formed on the column of the copper pillar, and the barrier layer prevents the diffusion of copper ions, so that the quality of the bump structure is enhanced.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1˜FIG. 5 respectively are a flowchart of a bumping process of a conventional wafer.

FIG. 6˜FIG. 11B respectively are a flowchart of a bumping process according to a preferred embodiment of the invention.

FIG. 10A˜FIG. 11A are diagrams of forming a solder layer on a barrier layer using electroplating

FIG. 10B˜FIG. 11B are diagrams of forming a solder layer on the copper layer using printing.

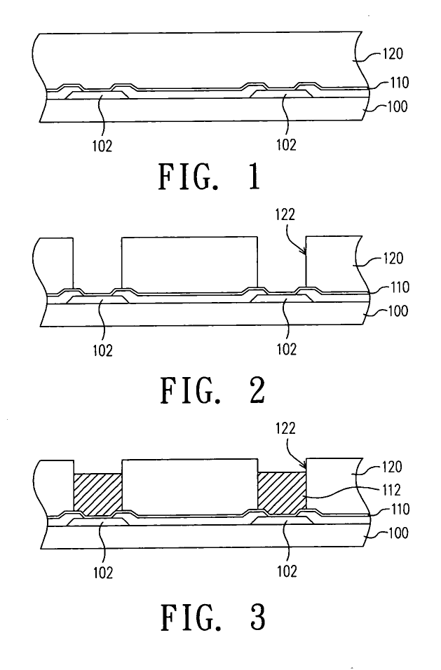

### DETAILED DESCRIPTION OF THE INVENTION

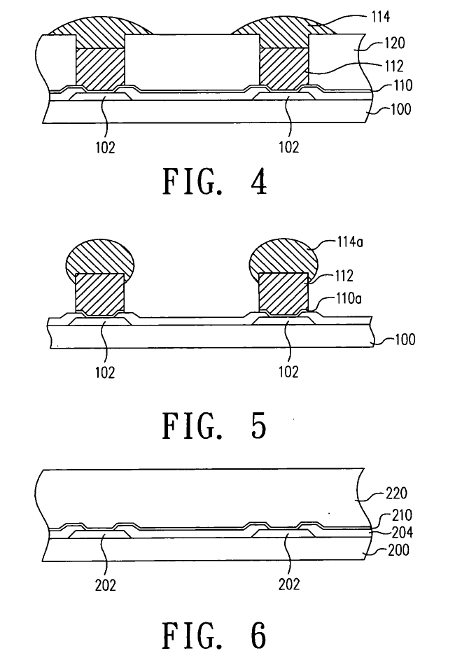

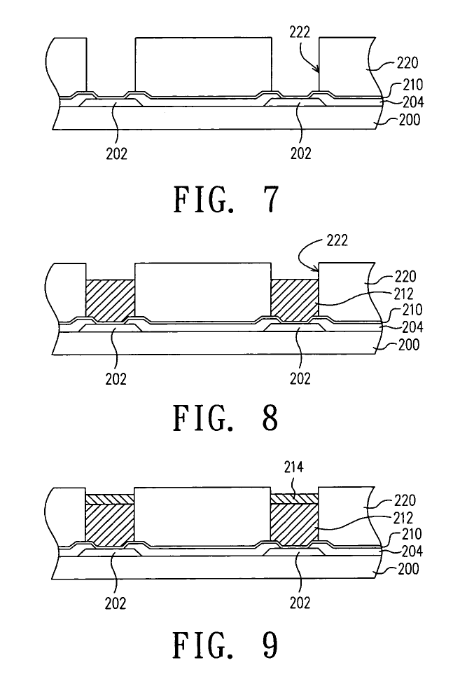

Referring to FIG. 6˜FIG. 11, flowcharts of a bumping process according to a preferred embodiment of the invention are shown. At first, referring to FIG. 6, a wafer 200 is provided, wherein the wafer 200 has several chips (not illustrated in the diagram), and the active surface of every chip has several bonding pads 202 which are exposed in the opening of the passivation layer. Next, an under bump metallurgy 210 is formed on the entire surface of the wafer 200, wherein the under bump metallurgy 210 can be a multiple-layered metal such as copper, nickel, vanadium, and chromium. The under bump metallurgy 210 can be formed on the surface of the wafer 200 using sputtering, evaporating or electroplating for instance, serving as a seed layer for the copper layer and the barrier layer in subsequent electroplating treatment. The present embodiment is exemplified by the electroplating manufacturing process. If the invention is embodied by non-electroplating manufacturing process, the under bump metallurgy 210 does not need to be formed on the surface of the wafer 200 beforehand. Besides, the active surface of the wafer 200, in response to the chip structure positioned at different contacting positions, can re-manufacture a re-distribution layer (RDL) (not illustrated in the diagram) and form the under bump metallurgy 210 on the RDL to proceed with the subsequent electroplating manufacturing process. Next, a photosensitive material is coated on the under bump metallurgy 210 to form a photo-resist layer 220.

Next, referring to FIG. 7, several openings 222 are formed on the photo-resist layer 220 using the imaging technology of exposure and development, and the openings 222 respectively expose the under bump metallurgy 210 disposed at the bottom. Next, referring to FIG. 8, the under bump metallurgy 210 is used as an electroplating-seed layer in copper electroplating treatment to form the copper post 212 of appropriate height or the first copper pillar in the opening 222. By controlling parameters such as concentration of copper ions in electroplating solution, current time/ampere and so forth, the height of the copper post 212 enables the educts of copper to be adhered onto the under bump metallurgy 210, and the thickness of the copper post 212 can range from 10 nm to 100 nm, from 10 nm to 50 nm, or is preferably controlled between 40 nm and 50 nm.

Next, referring to FIG. 9, a barrier layer 214 is formed on the copper post 212 disposed in the opening 222, wherein the barrier layer 214 can be made of the materials such as nickel or other materials capable of suppressing the diffusion of copper ions. The barrier layer 214 can use the spherical metal layer 210 as an electroplating-seed layer by electroplating for the educts of nickel in the electroplating solution to be adhered onto the copper post 212. In the present embodiment, the thickness of the barrier layer 214 is far thinner than the thickness of the copper post 212. However, the thickness is preferably larger than 3 nm but smaller than 10 nm.

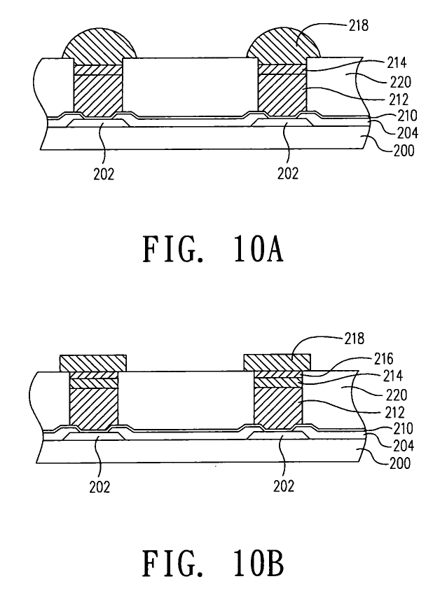

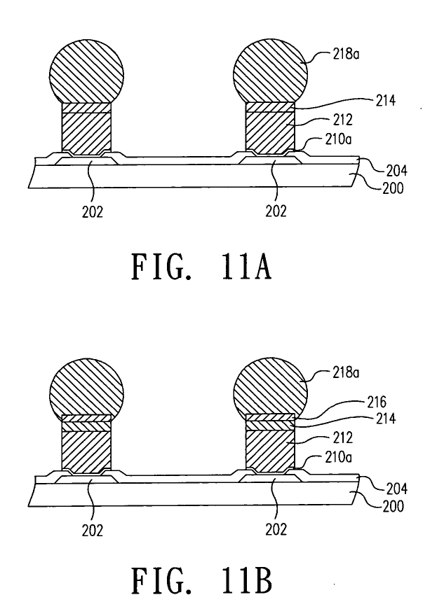

Next, referring to FIG. 10A and FIG. 10B, a solder layer 218 is formed on the barrier layer 214. The solder layer 218 can be formed by electroplating or printing, and the solder layer 214 can be made of materials such as tin-lead alloy with a low melting point or other metals. Referring to FIG. 10A, take the electroplating treatment for example. By controlling parameters such as concentration of metal ions in the electroplating solution, the height of the solder layer 218 enables the metal educts to be directly adhered onto the barrier layer 210. At last, the solder bump 218a of FIG. 11A is formed. Besides, referring to FIG. 10B, the solder layer 218 is formed by printing, a copper layer 216 also called adhering layer is formed by electroplating, and a solder layer 218 is formed on the copper layer 216 by screen printing, so that the adherence of the solder is enhanced. The thickness of the copper layer 216 is preferably smaller than 1 nm. At last, the solder bump 218a of FIG. 11B is formed.

Next, referring to FIG. 11A and FIG. 11B, the photo-resist layer 220 is removed, and the portion of the under bump metallurgy 210 not covered by the copper post 212 is etched except the portion of the under bump metallurgy 210a disposed at the bottom of the copper post 212, then the solder layer 218 of FIG. 11 is reflown to form a spherical or semi-spherical solder bump 218a. In the present embodiment, a barrier layer 214 is disposed between the solder bump 218a and the copper post 212, so as to prevent the diffusion and loss of copper ions on the copper post 212. Besides, in FIG. 11, the height of the copper post 212 and the quality of the bump would not be affected despite copper ions are lost due to the direct contact between the copper layer 216 and the solder bump 218a. After the bumping process of the copper post 212, the barrier layer 214, the copper layer 216, and printing or electroplating the solder layer 216 on the surface of the wafer 200 is completed, the wafer 200 can be divided into several independent chips (not illustrated in the diagram), and every chip can be electrically connected to an external electronic device such as a circuit board for instance via the above bump for signals to be transmitted.

It can be seen from the above disclosure that in the bumping process of the invention and the bump structure thereof, a barrier layer is formed between the copper post and the copper layer/the solder layer, or a barrier layer is formed between a copper post and a solder layer, so that the loss rate of copper ions are mitigated. Therefore, the solder bump can be formed on the column of the copper pillar, and the barrier layer prevents the diffusion of copper ions, so that the quality of the bump structure is enhanced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bumping process comprising the steps of:
providing a wafer, wherein the wafer has a plurality of chips each having at least a bonding pad positioned on an active surface of the wafer;
forming an under bump metallurgy (UBM) on the active surface of the wafer;
forming a photo-resist layer on the active surface of the wafer and forming at least an opening in the photo-resist layer;
sequentially forming a copper post, a barrier and a copper layer;
removing the photo-resist layer; and
reflowing a solder layer in the opening.

2. The bumping process according to claim 1, wherein the method of forming the photo-resist layer comprises coating a photosensitive material and forming the opening using exposure and development.

3. The bumping process according to claim 1, wherein the step of forming the solder layer is screen printed on the copper layer and disposed in the opening.

4. The bumping process according to claim 1, wherein after the formation of the wafer, the process further comprises forming a re-distribution layer (RDL) on an active surface of the wafer.

5. The bumping process according to claim 4, wherein after the formation of the RDL, the process further comprises forming an under bump metallurgy (UBM) on the RDL with a portion of the surface of the under bump metallurgy being exposed in the opening.

6. A bump structure applicable to a chip, wherein the chip has at least a bonding pad positioned on an active surface of the chip, the bump structure comprises:
a column having a copper post, a barrier layer and a copper layer, wherein the copper post connects the bonding pad, and the barrier layer is connecting the copper post and the copper layer;
a solder bump disposed on the copper layer of the column; and
a spherical metal layer, connecting to the bonding pad and the cooper post.

7. The bump structure according to claim 6, wherein the thickness of the barrier layer is larger than the thickness of the copper layer.

8. The bump structure according to claim 6, wherein the thickness of the copper post is larger than the thickness of the resist layer.

9. The bump structure according to claim 6, wherein the thickness of the copper post ranges from 10 nm to 100 nm.

10. The bump structure according to claim 9, wherein the thickness of the copper post ranges from 10 nm to 50 nm.

11. The bump structure according to claim 9, wherein the thickness of the copper post ranges from 40 nm to 50 nm.

12. The bump structure according to claim 6, wherein the thickness of the barrier layer is larger than 3 nm but smaller than 10 nm.

13. The bump structure according to claim 6, wherein the thickness of the copper layer is smaller than 1 nm.

14. The bump structure according to claim 6, wherein the column is a cylinder.

15. The bump structure according to claim 6, wherein the barrier layer is made of nickel.

16. The bump structure according to claim 6, wherein the solder bump comprises tin.
